(19) United States
(12) Patent Application Publication
(10) Pub. No.: US 2025/0040145 A1
(43) Pub. Date: Jan. 30, 2025

(54) SEMICONDUCTOR MEMORY DEVICE

(71) Applicant: SAMSUNG ELECTRONICS CO., LTD., Suwon-si (KR)

(72) Inventors: Bonjae KOO, Suwon-si (KR); Seulji Song, Suwon-si (KR); Youngsun Song, Suwon-si (KR)

(73) Assignee: SAMSUNG ELECTRONICS CO., LTD., Suwon-si (KR)

(21) Appl. No.: 18/786,011

(22) Filed: Jul. 26, 2024

(30) Foreign Application Priority Data
Jul. 28, 2023 (KR) 10-2023-0099000

(51) Int. Cl. H10B 51/20; H01L 29/78; H10B 51/10; H10B 51/40

(52) U.S. Cl. CPC H10B 51/20; H01L 29/78391; H10B 51/10; H10B 51/40

(57) ABSTRACT

A semiconductor memory device is provided. The semiconductor device includes: a stacked structure with word line plates and mold insulating layers which extend in first and second horizontal directions, and are alternately stacked in a vertical direction in a cell array region and an extension region, the plurality of word line plates forming a staircase structure in the extension region; a vertical bit line extending into the stacked structure in the cell array region; a plurality of selection layers between the plurality of word line plates and the vertical bit line; and a vertical channel transistor connected to one end of the vertical bit line. A first thickness of each of the plurality of mold insulating layers is about 1.5 times to about 3 times a second thickness of each of the plurality of word line plates.

### CROSS-REFERENCE TO RELATED APPLICATION

This application claims priority to Korean Patent Application No. 10-2023-0099000, filed on Jul. 28, 2023, in the Korean Intellectual Property Office, the disclosure of which is incorporated by reference herein in its entirety.

### BACKGROUND

The present disclosure relates to a semiconductor memory device, and more particularly, to a vertical semiconductor memory device having a three-dimensional structure.

To improve performance and reduce manufacturing complexity, there is a need for increased integration of memory devices. In particular, the degree of integration of two-dimensional memory devices is dependent on an area occupied by a unit memory cell, the integration of the two-dimensional memory devices is largely influenced by the level of a fine pattern forming technique. Pieces of complex equipment are required to form a fine pattern, and the area of a chip die is limited. Therefore, the integration of two-dimensional memory devices has been increasing but is still limited. Accordingly, there is a need for vertical memory devices having a three-dimensional structure.

### SUMMARY

Example embodiments provide a vertical semiconductor memory device having a three-dimensional structure with improved electrical characteristics by forming the thickness of a mold insulating layer between word line plates to be relatively greater than the thickness of the word line plate.

Example embodiments also provide a vertical semiconductor memory device having a three-dimensional structure, capable of reducing an area occupied by supports in an extension area by forming the thickness of a mold insulating layer between word line plates to be relatively greater than the thickness of the word line plate, thereby improving the degree of integration.

Example embodiments are not limited thereto, and other objects will be clearly understood by those skilled in the art from the following description.

According to an aspect of an example embodiment, a semiconductor memory device includes: a stacked structure including a plurality of word line plates and a plurality of mold insulating layers which extend in a first horizontal direction and a second horizontal direction, and are alternately stacked in a vertical direction in a cell array region and an extension region, the first horizontal direction crossing the second horizontal direction and the plurality of word line plates forming a staircase structure in the extension region; a vertical bit line extending into the stacked structure in the cell array region; a plurality of selection layers between the plurality of word line plates and the vertical bit line; and a vertical channel transistor connected to one end of the vertical bit line. A first thickness of each of the plurality of mold insulating layers is about 1.5 times to about 3 times a second thickness of each of the plurality of word line plates.

According to another aspect of an example embodiment, a semiconductor memory device includes: a stacked structure including a plurality of word line plates and a plurality of mold insulating layers alternately stacked in a cell array region and an extension region, a first thickness of each of the plurality of mold insulating layers being about 1.5 times to about 3 times a second thickness of each of the plurality of word line plates; a plurality of word line cuts extending in a horizontal direction, and extending into the stacked structure in a vertical direction in the cell array region and the extension region; a peripheral circuit structure beneath the stacked structure and including a peripheral circuit; a plurality of cell metal contacts extending through at least one of the plurality of word line plates in the extension region to be electrically connected to the peripheral circuit of the peripheral circuit structure; a vertical bit line extending into the stacked structure in the cell array region; a plurality of selection layers, each of the plurality of selection layers including a selective material between a corresponding word line plate and the vertical bit line, a first selective electrode between the selective material and the vertical bit line, and a second selective electrode between the corresponding word line plate and the selective material; and a vertical channel transistor connected to one end of the vertical bit line.

According to another aspect of an example embodiment, a semiconductor memory device includes: a stacked structure including a plurality of word line plates and a plurality of mold insulating layers alternately stacked, a first thickness of each of the plurality of mold insulating layers being about 1.5 times to about 3 times a second thickness of each of the plurality of word line plates; a vertical bit line extending into the stacked structure; and a plurality of selection layers between the plurality of word line plates and the vertical bit line.

### BRIEF DESCRIPTION OF DRAWINGS

The above and other aspects and features of the present disclosure will be more clearly understood from the following description of example embodiments, taken in conjunction with the accompanying drawings, in which:

FIG. 1 is a perspective view illustrating components of a semiconductor memory device according to an example embodiment;

FIGS. 2A, 2B and 2C are a perspective view, a top view, and a cross-sectional view illustrating a memory cell and a memory cell string of a semiconductor memory device according to an example embodiment;

FIGS. 3A, 3B and 3C are a perspective view, a top view, and a cross-sectional view illustrating a vertical channel transistor of a semiconductor memory device according to an example embodiment;

FIGS. 4A, 4B and 4C are graphs illustrating changes in characteristics according to a thickness of a mold insulating layer of a semiconductor memory device according to an example embodiment;

FIGS. 5A and 5B are a top view and a cross-sectional view illustrating an extension region of a semiconductor memory device according to an example embodiment; and

FIGS. 6 to 10 are top views illustrating semiconductor memory devices according to example embodiments.

### DETAILED DESCRIPTION

Hereinafter, example embodiments are described in detail with reference to the accompanying drawings. Like components are denoted by like reference numerals throughout the specification, and repeated descriptions thereof are omitted. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present.

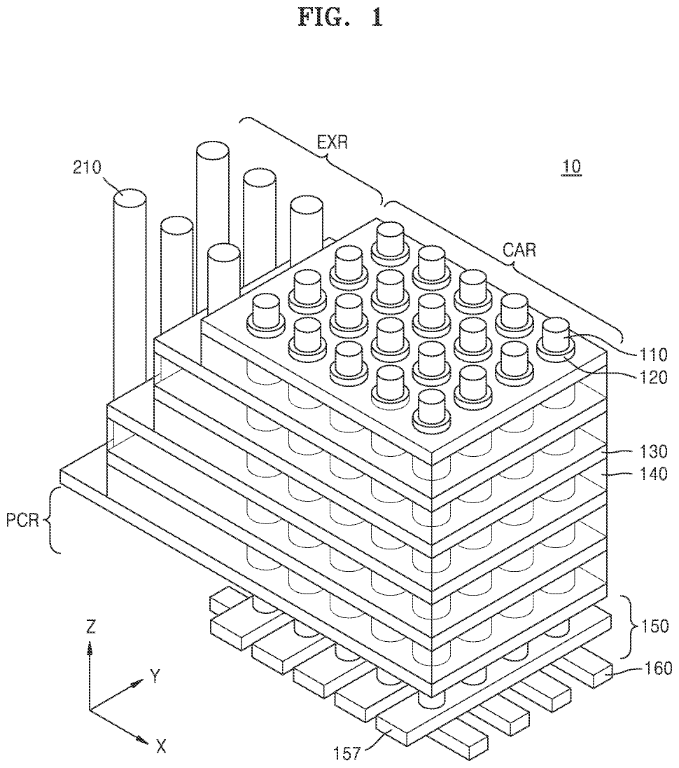

FIG. 1 is a perspective view illustrating components of a semiconductor memory device 10 according to an example embodiment.

Referring to FIG. 1, the semiconductor memory device 10 may include a cell array region CAR and an extension region EXR on a peripheral circuit region PCR.

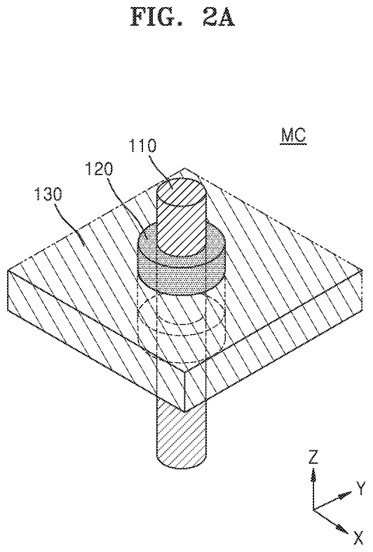

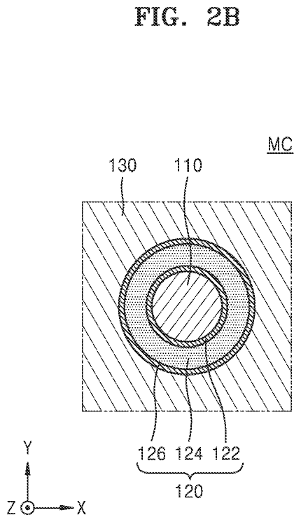

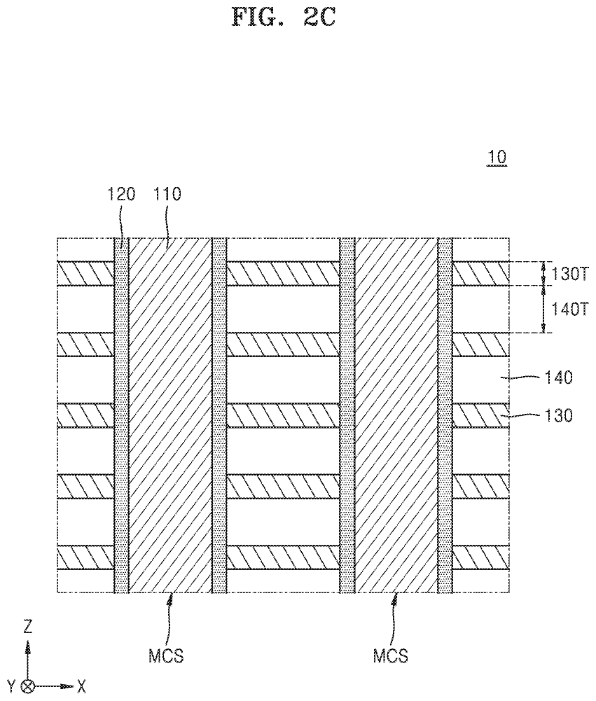

The semiconductor memory device 10 may be a vertical memory device having a three-dimensional structure including selector-only memory (SOM) or self-selecting memory (SSM). A plurality of selectors 120 between one vertical bit line 110 and a plurality of word line plates 130 may constitute one memory cell string MCS (see FIG. 2C). A memory cell string MCS (see FIG. 2C) may include a plurality of memory cells MC (see FIG. 2A) in the vertical direction (the Z direction). In addition, a plurality of memory cell strings MCS (see FIG. 2C) may constitute the cell array region CAR.

In the cell array region CAR, a plurality of vertical bit lines 110, a plurality of word line plates 130, and a plurality of selectors 120 (i.e., selection layers) between the plurality of vertical bit lines 110 and the plurality of word line plates 130. A vertical bit line 110, a word line plate 130, and a selector 120 between the vertical bit line 110 and the word line plate 130 may constitute a memory cell MC (see FIG. 2A).

The plurality of vertical bit lines 110 may be separated from each other in a first horizontal direction (the X direction) and a second horizontal direction (the Y direction) perpendicular to each other, and extend in the vertical direction (the Z direction). The plurality of vertical bit lines 110 may have a matrix arrangement in a top view but are not limited thereto. For example, the plurality of vertical bit lines 110 may have a hexagonal arrangement in a top view. A vertical bit line 110 may be referred to as a vertical pillar.

Each of the plurality of vertical bit lines 110 may have a cylindrical shape, but example embodiments are not limited thereto. For example, each of the plurality of vertical bit lines 110 may have a square pillar shape. The plurality of vertical bit lines 110 may include a conductive material. For example, the plurality of vertical bit lines 110 may include doped polysilicon, a metal, conductive metal nitride, or a combination thereof.

Each of the plurality of word line plates 130 may have a plate shape extending in the first horizontal direction (the X direction) and the second horizontal direction (the Y direction). The plurality of word line plates 130 may be separated from each other in the vertical direction (the Z direction). The plurality of word line plates 130 may include, for example, doped silicon, a metal, conductive metal nitride, conductive metal silicide, or a combination thereof.

The plurality of selectors 120 may surround at least portions of the plurality of vertical bit lines 110, respectively. In a top view, a selector 120 may have a ring shape surrounding a corresponding vertical bit line 110. In some example embodiments, the selector 120 may have a circular ring shape in a top view, but example embodiments are not limited thereto. In some example embodiments, in a top view, the shape of the selector 120 may be determined according to the shape of the vertical bit line 110. For example, when the vertical bit line 110 has a square pillar shape, the shape of the selector 120 in a top view may have a square ring shape.

In some example embodiments, the top of each of the plurality of selectors 120 may be at a higher vertical level than the upper surface of the highest word line plate 130 among the plurality of word line plates 130, but example embodiments are not limited thereto. For example, the top of each of the plurality of selectors 120 may be at the same vertical level as the upper surface of the highest word line plate 130 among the plurality of word line plates 130.

In some example embodiments, the bottom of each of the plurality of selectors 120 may be at a lower vertical level than the lower surface of the lowest word line plate 130 among the plurality of word line plates 130, but example embodiments are not limited thereto. For example, the bottom of each of the plurality of selectors 120 may be at the same vertical level as the lower surface of the lowest word line plate 130 among the plurality of word line plates 130.

In some example embodiments, for example as shown in FIG. 2C, the selector 120 included in the memory cell string MCS extends from the upper surface of the highest word line plate 130 among the plurality of word line plates 130 to the lower surface of the lowest word line plate 130 among the plurality of word line plates 130 and surrounds the vertical bit line 110, example embodiments are not limited thereto. For example, each of the plurality of memory cell strings MCS may include a plurality of selectors 120 which surround respective portions of a vertical bit line 110 corresponding to the plurality of word line plates 130 and are separated from each other.

In some example embodiments, for example as shown in FIG. 2C, one memory cell string MCS may include one vertical bit line 110 and one selector 120 integrally extending between the one vertical bit line 110 and the plurality of word line plates 130. In some example embodiments, one memory cell string MCS may include one vertical bit line 110 and a plurality of selectors 120 between the one vertical bit line 110 and the plurality of word line plates 130, respectively, and separated from each other in the vertical direction (the Z direction).

A plurality of mold insulating layers 140 may be provided between the plurality of word line plates 130. For example, the plurality of word line plates 130 and the plurality of mold insulating layers 140 may be alternately disposed in the vertical direction (the Z direction). In the cell array region CAR, a stacked structure of the plurality of word line plates 130 and the plurality of mold insulating layers 140 may be referred to as a word line structure.

The plurality of vertical bit liens 110 may extend in the vertical direction (the Z direction) by penetrating the word line structure, i.e., the stacked structure of the plurality of word line plates 130 and the plurality of mold insulating layers 140 alternately stacked in the vertical direction (the Z direction). For example, the plurality of mold insulating layers 140 may include silicon oxide or an insulating material having a lower dielectric constant than the silicon oxide. In some example embodiments, the plurality of mold insulating layers 140 may include a tetraethyl orthosilicate (TEOS) layer or a low dielectric material layer having a low dielectric constant. The low dielectric material layer may include a silicon oxycarbide (SiOC) layer or a hydrogenated silicon oxycarbide (SiOCH) layer.

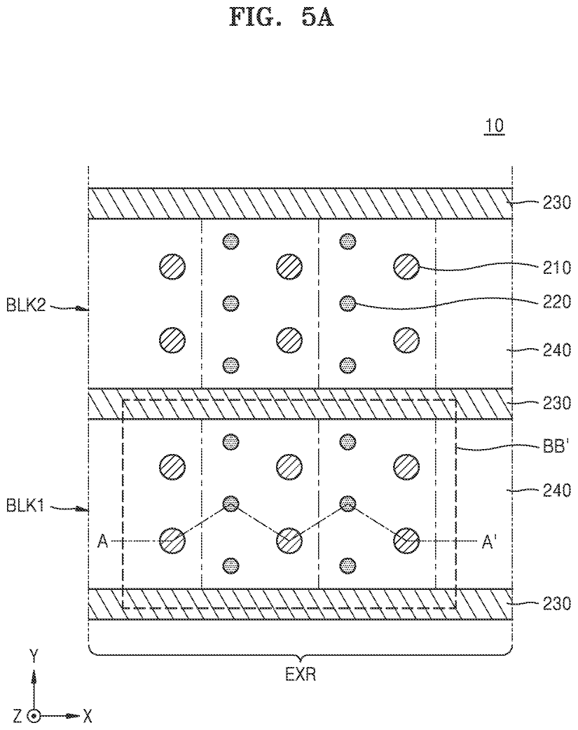

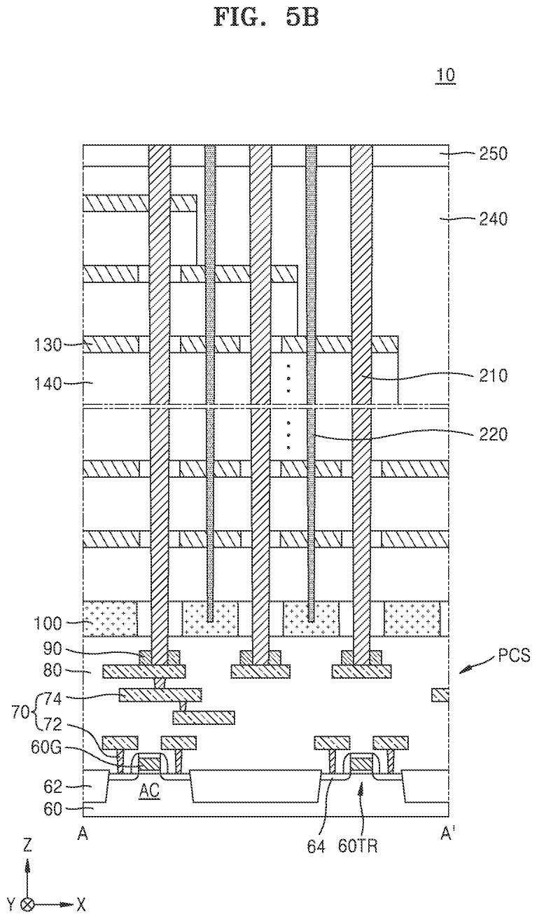

In the semiconductor memory device 10, for example, as shown in FIG. 2C, a thickness 140T of each of the plurality of mold insulating layers 140 in the vertical direction (the Z direction) may be about 1.5 times to about 3 times a thickness 130T of each of the plurality of word line plates 130 in the vertical direction (the Z direction). The difference in the thickness 140T of each mold insulating layer 140 may improve the electrical characteristics of a memory device related to a word line plate 130. In addition, the increased thickness 140T of each mold insulating layer 140 may allow for a reduction in an area occupied by a support 220 (see FIG. 5A) in the extension region EXR.

Accordingly, in a limited area of a chip die, the area of the extension region EXR may be relatively reduced and the area of the cell array region CAR may be increased, and thus, the integration of the semiconductor memory device 10 may be improved. This improvement of the integration of the semiconductor memory device 10 is described in detail below.

FIGS. 2A to 2C are a perspective view, a top view, and a cross-sectional view illustrating a memory cell MC and a memory cell string MCS of a semiconductor memory device, such as the semiconductor memory device 10 of FIG. 1.

Referring to FIGS. 2A to 2C, the memory cell MC is a unit cell including a vertical bit line 110, a word line plate 130, and a selector 120 between the vertical bit line 110 and the word line plate 130.

The memory cell string MCS may include, for example, a plurality of memory cells MC in the vertical direction (the Z direction). In some example embodiments, the memory cell string MCS may include a plurality of memory cells MC corresponding to the number of word line plates 130.

A portion of the selector 120 corresponding to one memory cell MC that is between the vertical bit line 110 and one word line plate 130 may be referred to as a selective unit. That is, the one memory cell MC may include the vertical bit line 110, the word line plate 130, and the selective unit that is a portion of the selector 120 between the vertical bit line 110 and the word line plate 130. For example, one memory cell string MCS may include, as a plurality of selective units, portions of the selector 120 respectively corresponding to the number of word line plates 130. In some example embodiments, the plurality of selective units may be a plurality of selectors 120 separated from each other in the vertical direction (the Z direction), respectively.

In some example embodiments, the selector 120 may include a first selective electrode layer 122, a selective material layer 124, and a second selective electrode layer 126. The first selective electrode layer 122 may be between the vertical bit line 110 and the selective material layer 124, and the second selective electrode layer 126 may be between a word line plate 130 and the selective material layer 124.

In some example embodiments, the first selective electrode layer 122 may extend in the vertical direction (the Z direction) along the plurality of word line plates 130 surrounding the vertical bit line 110 and surround the vertical bit line 110, but example embodiments are not limited thereto. For example, the first selective electrode layer 122 included in one memory cell string MCS may include a plurality of first selective electrode layers between the vertical bit line 110 and the plurality of word line plates 130 surrounding the vertical bit line 110, respectively, and separated from each other in the vertical direction (the Z direction). The second selective electrode layer 126 included in one memory cell string MCS may include a plurality of second selective electrode layers between the plurality of word line plates 130 and the selective material layer 124, respectively, and separated from each other in the vertical direction (the Z direction).

Each of the first selective electrode layer 122 and the second selective electrode layer 126 may include a conductive material, e.g., carbon or a conductive material containing carbon. The selective material layer 124 may include a material having an ovonic threshold switch (OTS) characteristic. For example, the selective material layer 124 may include a chalcogenide material.

For example, when the selector 120 includes a material having the OTS characteristic, if a voltage greater than or equal to a threshold voltage is applied to both ends of the selector 120, the resistance or threshold voltage of the selector 120 sharply decreases as a result of a threshold switching phenomenon, and thus, the selector 120 may be in a turn-on state in which a current flows through the selector 120. If a current less than or equal to a certain threshold current flows through the selector 120 in the turn-on state, the resistance or threshold voltage of the selector 120 sharply increases, and thus, the selector 120 may be in a turn-off state in which a current does not flow through the selector 120. Herein, the turn-on state and the turn-off state may correspond to other logic states (a SET state and a RESET state), respectively.

Herein, although the selector 120 may include the chalcogenide material having the OTS characteristic, example embodiments are not limited thereto. In some example embodiments, the selector 120 of the semiconductor memory device 10 may include various materials having a resistance change characteristic.

For example, when the selector 120 includes transition metal oxide, the semiconductor memory device 10 may be resistive random access memory (ReRAM).

Alternatively, when the selector 120 includes a ferroelectric, the semiconductor memory device 10 may be ferroelectric random access memory (FRAM). Alternatively, when the selector 120 has a magnetic tunnel junction structure including two electrodes of a magnetic body and a dielectric between the two magnetic electrodes, the semiconductor memory device 10 may be magnetic ferroelectric random access memory (MRAM).

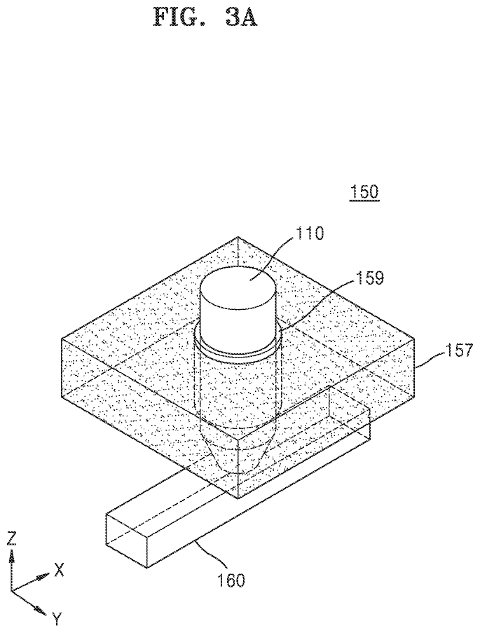

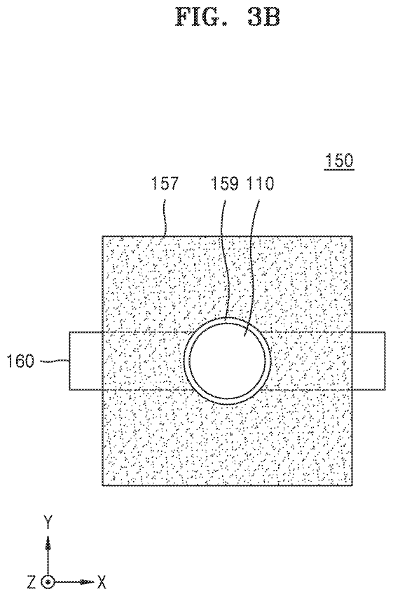

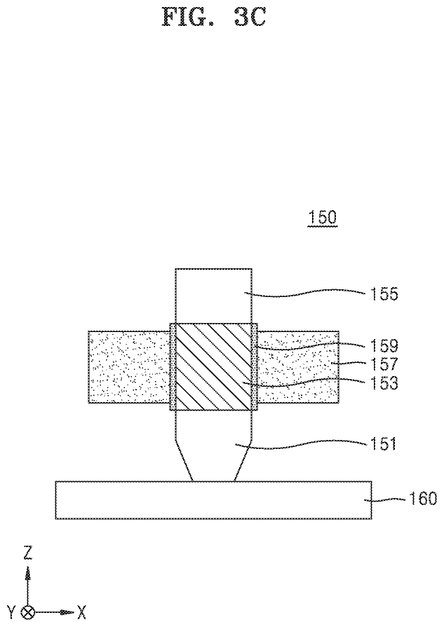

FIGS. 3A to 3C are a perspective view, a top view, and a cross-sectional view illustrating a vertical channel transistor 150 of a semiconductor memory device, such as the semiconductor memory device 10.

Referring to FIGS. 3A to 3C, a plurality of vertical channel transistors 150 may be on and/or beneath the cell array region CAR. Although FIG. 1 shows that the plurality of vertical channel transistors 150 are beneath the cell array region CAR, example embodiments are not limited thereto and the plurality of vertical channel transistors 150 may be on the cell array region CAR.

Each of the plurality of vertical channel transistors 150 may include a source region 151, a channel region 153, a drain region 155, a gate line 157, and a gate insulating layer 159 between the channel region 153 and the gate line 157. The source region 151, the channel region 153, and the drain region 155 corresponding to each other may be sequentially disposed in the vertical direction (the Z direction). Herein, the source region 151, the channel region 153, and the drain region 155 may be referred to as a semiconductor structure.

The semiconductor structure may include semiconductor material. In some example embodiments, the semiconductor structure may include monocrystalline silicon (Si) or polysilicon. In some example embodiments, the semiconductor structure may include a two-dimensional (2D) semiconductor material or an oxide semiconductor material. For example, the 2D semiconductor material may include molybdenum sulfide (MoS), tungsten selenide (WSe), graphene, a carbon nanotube, or a combination thereof. In addition, the oxide semiconductor material may include indium gallium zinc oxide (InGaZnO), indium gallium silicon oxide (InGaSiO), indium tin zinc oxide (InSnZnO), indium zinc oxide (InZnO), zinc oxide (ZnO), zinc tin oxide (ZnSnO), zirconium zinc tin oxide (ZrZnSnO), tin oxide (SnO), hafnium indium zinc oxide (HfInZnO), gallium zinc tin oxide (GaZnSnO), aluminum zinc tin oxide (AlZnSnO), ytterbium gallium zinc oxide (YbGaZnO), indium gallium oxide (InGaO), or a combination thereof. For example, the semiconductor structure may include a single layer or multiple layers of the oxide semiconductor material. In some example embodiments, the semiconductor structure may include a material having a bandgap energy higher than the bandgap energy of Si. For example, the semiconductor structure may include a material having bandgap energy of about 1.5 eV to about 5.6 eV.

A plurality of horizontal bit lines 160 may extend in the first horizontal direction (the X direction) beneath the plurality of vertical channel transistors 150. For example, the plurality of horizontal bit lines 160 may extend in parallel to each other in the first horizontal direction (the X direction). The plurality of horizontal bit lines 160 may be separated from each other in the second horizontal direction (the Y direction). In some example embodiments, the plurality of horizontal bit lines 160 may be separated from each other at equal intervals in the second horizontal direction (the Y direction). A horizontal bit line 160 may be referred to as a bit line.

The source region 151, the channel region 153, and the drain region 155 constituting one vertical channel transistor 150 may be sequentially disposed in the vertical direction (the Z direction) from the horizontal bit line 160 toward the vertical bit line 110. In some example embodiments, the source region 151, the channel region 153, and the drain region 155 constituting one vertical channel transistor 150 may have substantially the same horizontal width and horizontal area. In some example embodiments, each of the source region 151 and the drain region 155 may have a first conductive type, and the channel region 153 may have a second conductive type other than the first conductive type.

The channel region 153 and the gate line 157 may be at substantially the same vertical level. The gate insulating layer 159 may be at substantially the same vertical level as each of the channel region 153 and the gate line 157. The source region 151 may be at a vertical level between the gate line 157 and the horizontal bit line 160. For example, the source region 151 may be at a lower vertical level than the gate line 157. The drain region 155 may be at a vertical level between the gate line 157 and the vertical bit line 110. For example, the drain region 155 may be at a higher vertical level than the gate line 157.

The gate line 157 may extend in the second horizontal direction (the Y direction) and surround the channel region 153. For example, a plurality of gate lines 157 may extend in parallel to each other in the second horizontal direction (the Y direction) and be separated from each other in the first horizontal direction (the X direction). In some example embodiments, the plurality of gate lines 157 may be separated from each other at equal intervals in the first horizontal direction (the X direction). For example, the plurality of gate lines 157 and the plurality of horizontal bit lines 160 may extend while intersecting with each other.

The gate insulating layer 159 may include at least one selected from among silicon oxide, a high-k dielectric material having a higher dielectric constant than the silicon oxide, and a ferroelectric material. In some example embodiments, the gate insulating layer 159 may have a stacked structure of a first dielectric layer including the silicon oxide and a second dielectric layer including at least one selected from the high-k dielectric material and the ferroelectric material. For example, the high-k dielectric material and the ferroelectric material may include at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), bismuth iron oxide (BiFO), strontium titanium oxide (SrTiO), yttrium oxide (YO), aluminum oxide (AlO), and lead scandium tantalum oxide (PbScTaO).

Each of the horizontal bit line 160 and the gate line 157 may include, for example, doped silicon, a metal, conductive metal nitride, conductive metal silicide, or a combination thereof. In some example embodiments, the gate line 157 may include a conductive barrier layer and a conductive filling layer covering the conductive barrier layer. The conductive barrier layer may include, for example, a metal, conductive metal nitride, conductive metal silicide, or a combination thereof. The conductive filling layer may include, for example, doped silicon, ruthenium (Ru), ruthenium oxide (RuO), platinum (Pt), platinum oxide (PtO), iridium (Ir), iridium oxide (IrO), titanium (Ti), titanium nitride (TiN), tungsten (W), tungsten nitride (WN), tantalum (Ta), tantalum nitride (TaN), titanium aluminum nitride (TiAlN), titanium silicon nitride (TiSiN), tantalum aluminum nitride (TaAlN), tantalum silicon nitride (TaSiN), or a combination thereof.

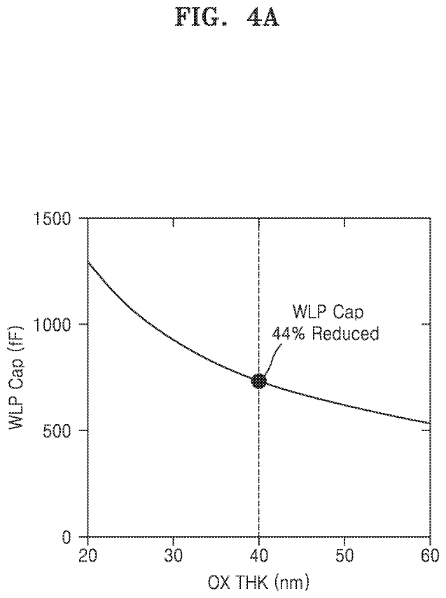

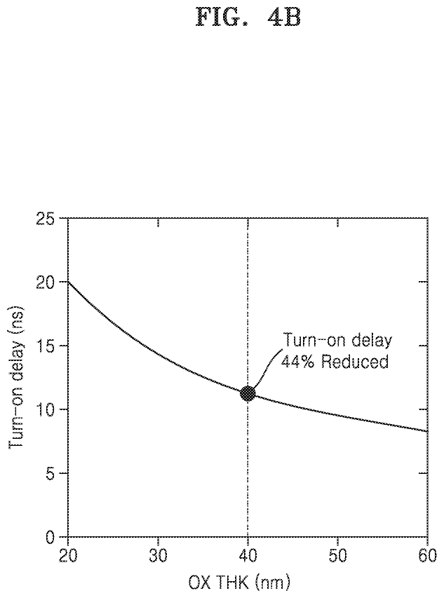

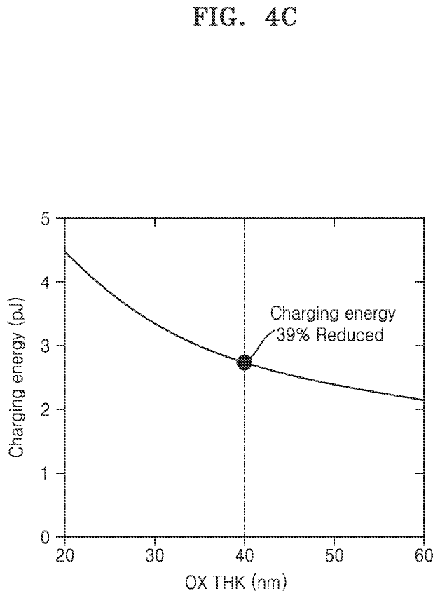

FIGS. 4A to 4C are graphs illustrating changes in characteristics according to a thickness OX THK of a molding insulating layer of a semiconductor memory device, such as the mold insulating layer 140 of the semiconductor memory device 10.

Referring to FIGS. 4A to 4C, changes in the electrical characteristics of the word line plate 130 (see FIG. 1) according to the thickness OX THK of the mold insulating layer 140 (see FIG. 1) are shown in various points of view.

To explain the electrical characteristics of the semiconductor memory device 10 (see FIG. 1), changes in the numeric values of a capacitance (shown in FIG. 4A), a turn-on delay (shown in FIG. 4B), and charging energy (shown in FIG. 4C) of the word line plate 130 were measured while the thickness of the word line plate 130 was fixed to 20 nm and the thickness OX THK of the mold insulating layer 140 changed from about 20 nm to about 60 nm.

In this case, compared to a point where the thickness OX THK of the mold insulating layer 140 is 20 nm (i.e., a point where the thickness OX THK of the mold insulating layer 140 is the same as the thickness of the word line plate 130), respective pieces of data measured at a point where the thickness OX THK of the mold insulating layer 140 is 40 nm (i.e., a point where the thickness OX THK of the mold insulating layer 140 is 2 times the thickness of the word line plate 130) are as follows.

Particularly, when the thickness OX THK of the mold insulating layer 140 is about 2 times the thickness of the word line plate 130, the capacitance of the word line plate 130 may be reduced by about 40%. In addition, the turn-on delay of the memory cell MC (see FIG. 2A) may be reduced by about 44%. In addition, the charging energy of the memory cell MC (see FIG. 2A) may be reduced by about 39%.

In this regard, it has been identified through experiments that the electrical characteristics of the semiconductor memory device 10 may be generally improved by optimizing the thickness OX THK of each of the plurality of mold insulating layers 140.

In the semiconductor memory device 10 according to example embodiments, when the thickness OX THK of each of the plurality of mold insulating layers 140 in the vertical direction (the Z direction) is about 1.5 times to about 3 times the thickness of each of the plurality of word line plates 130 in the vertical direction (the Z direction), the electrical characteristics (e.g., the capacitance, the turn-on delay, and the charging energy) of the semiconductor memory device 10 may be improved.

FIGS. 5A and 5B are a top view and a cross-sectional view illustrating the extension region EXR of a semiconductor memory device, such as the semiconductor memory device 10. Particularly, FIG. 5A is a top view illustrating a portion of the extension region EXR, and FIG. 5B is a cross-sectional view of the semiconductor memory device 10 taken along line A-A′ of FIG. 5A.

Referring to FIGS. 5A and 5B, the semiconductor memory device 10 may include a peripheral circuit structure PCS beneath the extension region EXR.

A substrate 60 may include a semiconductor material, e.g., a group IV semiconductor, a group III-V compound semiconductor, or a group II-VI oxide semiconductor. In some example embodiments, the group IV semiconductor may include Si, germanium (Ge), or SiGe. The substrate 60 may be provided as a bulk wafer or a wafer with an epitaxial layer. Alternatively, the substrate 60 may include a silicon on insulator (SOI) substrate or a germanium on insulator (GeOI) substrate.

In the substrate 60, an active region AC may be defined by a device isolation layer 62 and a plurality of peripheral circuit transistors 60TR may be formed on the active region AC. Each of the plurality of peripheral circuit transistors 60TR may include a peripheral circuit gate 60G and a source/drain region 64 in a portion of the substrate 60 at both sides of the peripheral circuit gate 60G.

In addition, the cell array region CAR (see FIG. 1) and the extension region EXR may be on the peripheral circuit region PCR (see FIG. 1) on the substrate 60. The peripheral circuit structure PCS may be in the peripheral circuit region PCR (see FIG. 1). The peripheral circuit structure PCS may include a peripheral circuit transistor 60TR and a peripheral circuit wiring 70 on the substrate 60.

The peripheral circuit structure PCS may include a peripheral circuit. The peripheral circuit may receive an address, a command, and a control signal from an apparatus outside the semiconductor memory device 10, and transmit and receive data to and from the apparatus outside the semiconductor memory device 10. The peripheral circuit may include a row decoder, a page buffer, a data input/output circuit, and a control logic. In some example embodiments, the peripheral circuit may further include an input/output interface, a column logic, a voltage generator, a pre-decoder, a temperature sensor, a command decoder, an address decoder, an amplification circuit, and the like.

The peripheral circuit wiring 70 may include a plurality of peripheral circuit contacts 72 and a plurality of peripheral circuit metal layers 74. An interlayer insulating layer 80 covering the peripheral circuit transistor 60TR and the peripheral circuit wiring 70 may be on the substrate 60. The plurality of peripheral circuit metal layers 74 may have a multi-layer structure including a plurality of layers at different vertical levels.

A common source plate 100 may be on the interlayer insulating layer 80. In some example embodiments, the common source plate 100 may function as a source region through which a current is supplied to memory cells formed in the cell array region CAR (see FIG. 1). The common source plate 100 may be under the cell array region CAR (see FIG. 1) and the extension region EXR above the substrate 60.

In some example embodiments, the common source plate 100 may include at least one of Si, Ge, SiGe, gallium arsenide (GaAs), indium gallium arsenide (InGaAs), aluminum gallium arsenide (AlGaAs), or a combination thereof. Alternatively, the common source plate 100 may include a semiconductor doped with n-type impurities. In addition, the common source plate 100 may have a crystal structure including any one selected from among a monocrystalline structure, an amorphous structure, and a polycrystalline structure.

In the extension region EXR, the plurality of word line plates 130 may constitute a pad structure. In the extension region EXR, the plurality of word line plates 130 that are farther away from the upper surface of the common source plate 100 may extend to have a shorter length in the first horizontal direction (the X direction) that word line plate 130 that are closer to the upper surface of the common source plate 100. For example, the word line plate 130 that is closest to the common source plate 100 may have the longest length in the first horizontal direction (the X direction). The pad structure may indicate portions of the plurality of word line plates 130 disposed in a staircase shape in the extension region EXR.

A cover insulating layer 240 may be on the pad structure, and an upper insulating layer 250 may be on the highest mold insulating layer 140 and the cover insulating layer 240. A plurality of cell metal contacts 210 may penetrate the upper insulating layer 250, the cover insulating layer 240, the plurality of word line plates 130, and the plurality of mold insulating layers 140 in the extension region EXR.

The plurality of cell metal contacts 210 electrically connecting the plurality of word line plates 130 to the peripheral circuit structure PCS may be in the extension region EXR of the semiconductor memory device 10. Each of the plurality of cell metal contacts 210 may be electrically connected to the peripheral circuit included in the peripheral circuit structure PCS. In some example embodiments, each of the plurality of cell metal contacts 210 may be electrically connected to different components of the peripheral circuit included in the peripheral circuit structure PCS.

Each of the plurality of cell metal contacts 210 may be electrically connected to one word line plate 130 corresponding thereto and separated from other word line plates 130 at a lower vertical level than that of the one word line plate 130 among the plurality of word line plates 130. A bottom portion of each of the plurality of cell metal contacts 210 may be surrounded by a conductive landing via 90, and the conductive landing via 90 may be covered by the interlayer insulating layer 80. The bottom surface of the conductive landing via 90 may be in contact with the upper surface of a peripheral circuit metal layer 74. The conductive landing via 90 may include, for example, polysilicon doped with impurities.

In addition, a plurality of supports 220 penetrating the upper insulating layer 250, the cover insulating layer 240, the plurality of word line plates 130, and the plurality of mold insulating layers 140 may be in the extension region EXR. In a top view, the plurality of supports 220 may be around the plurality of cell metal contacts 210. Arrangement relationships of the plurality of supports 220 and the plurality of cell metal contacts 210 according to example embodiments are described below.

The plurality of supports 220 may include, for example, at least one selected from among silicon oxide, silicon nitride, and silicon oxynitride (SiON). The plurality of supports 220 may be formed in a cylindrical shape to reduce bending of the mold insulating layer 140 and improve structural stability in a process of manufacturing the semiconductor memory device 10, including a process of replacing a sacrificial layer with the word line plate 130. However, when the number of supports 220 increases, an area occupied by the extension region EXR may also increase, and thus, an area occupied by the cell array region CAR (see FIG. 1) in the semiconductor memory device 10 may relatively decrease such that the degree of integration decreases.

A plurality of word line cuts 230 may extend on the common source plate 100 in the first horizontal direction (the X direction) in parallel to the upper surface of the common source plate 100. The plurality of word line cuts 230 may include, for example, silicon oxide, silicon nitride, SiON, silicon oxycarbonitride (SiOCN), silicon carbonitride (SiCN), or a combination thereof but are not limited thereto.

In some example embodiments, a plurality of word line plates 130 between a pair of word line cuts 230 facing each other may constitute one block. For example, FIG. 5A illustrates a first block BLK1 and a second block BLK2.

In the semiconductor memory device 10, the thickness of the mold insulating layer 140 may be formed to be about 1.5 times to about 3 times the thickness of the word line plate 130 to improve the supporting force of the mold insulating layer 140, thereby reducing bending of the mold insulating layer 140 while also allowing for a reduced number of supports 220. Accordingly, in a limited area of a chip die, the area of the extension region EXR may be relatively reduced and the area of the cell array region CAR (see FIG. 1) may be relatively increased, and thus, the integration of the semiconductor memory device 10 may be improved.

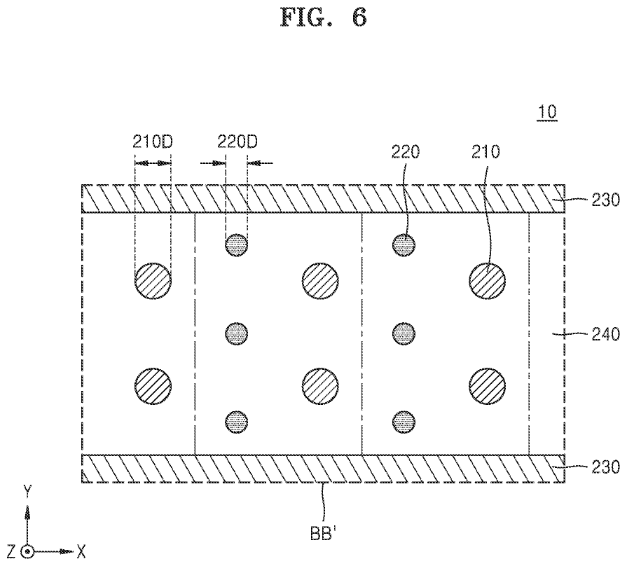

FIGS. 6 to 10 are top views illustrating semiconductor memory devices according to various example embodiments. Particularly, FIGS. 6 to 10 are top views corresponding to area BB′ of FIG. 5A.

Referring to FIG. 6, the semiconductor memory device 10 may include the plurality of cell metal contacts 210 and the plurality of supports 220 in the extension region EXR (see FIG. 5A).

The semiconductor memory device 10 according to example embodiments may include, in the extension region EXR (see FIG. 5A), the plurality of word line cuts 230 extending in the first horizontal direction (the X direction), and cutting a stacked structure of the plurality of word line plates 130 (see FIG. 5B) and the plurality of mold insulating layers 140 (see FIG. 5B) in the vertical direction (the Z direction).

As described above, the semiconductor memory device 10 may include, in the extension region EXR (see FIG. 5A), the plurality of cell metal contacts 210 electrically connected to one word line plate 130 (see FIG. 5B) among the plurality of word line plates 130 (see FIG. 5B) while penetrating the one word line plate 130 (see FIG. 5B), electrically isolated from other word line plates 130 (see FIG. 5B) under the one word line plate 130 (see FIG. 5B) while penetrating the other word line plates 130 (see FIG. 5B), and electrically connected to a peripheral circuit of the peripheral circuit structure PCS (see FIG. 5B).

Herein, two cell metal contacts 210 may be in a line in the second horizontal direction (the Y direction) between two of the plurality of word line cuts 230 facing each other. In addition, cylindrical-shaped supports 220 may be between cell metal contacts 210 facing each other in the first horizontal direction (the X direction).

Because the semiconductor memory device 10 according to example embodiments may include a relatively small number of supports 220, the number of supports 220 arranged in a line in the second horizontal direction (the Y direction) between the two of the plurality of word line cuts 230 facing each other may be 3. In addition, accordingly, a diameter 220D of each support 220 may be less than a diameter 210D of each cell metal contact 210. For example, the diameter 210D of a cell metal contact 210 may be about 1.5 times to about 2.5 times the diameter 220D of a support 220.

The number of supports 220 may be further reduced as the thickness of the mold insulating layer 140 (see FIG. 5B) increases. Because a thick mold insulating layer 140 (see FIG. 5B) has a supporting force, a problem, such as bending, is reduced. Accordingly, the number of supports 220 for supporting the mold insulating layer 140 (see FIG. 5B) may be reduced, and the area of the extension region EXR (see FIG. 5A) may be reduced, thereby increasing the area of the cell array region CAR (see FIG. 1). In the semiconductor memory device 10, an increase in the area of the cell array region CAR (see FIG. 1) may increase the degree of integration.

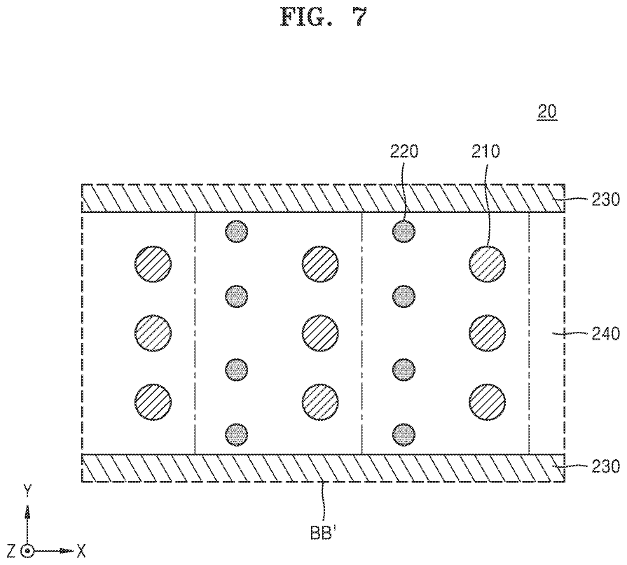

Referring to FIG. 7, a semiconductor memory device 20 may include the plurality of cell metal contacts 210 and the plurality of supports 220 in the extension region EXR (see FIG. 5A).

The semiconductor memory device 20 according to example embodiments may include, in the extension region EXR (see FIG. 5A), the plurality of word line cuts 230 extending in the first horizontal direction (the X direction), and cutting a stacked structure of the plurality of word line plates 130 (see FIG. 5B) and the plurality of mold insulating layers 140 (see FIG. 5B) in the vertical direction (the Z direction).

Herein, three cell metal contacts 210 may be in a line in the second horizontal direction (the Y direction) between two of the plurality of word line cuts 230 facing each other. In addition, cylindrical-shaped supports 220 may be between cell metal contacts 210 facing each other in the first horizontal direction (the X direction).

Because the semiconductor memory device 20 may include a relatively small number of supports 220, the number of supports 220 arranged in a line in the second horizontal direction (the Y direction) between the two of the plurality of word line cuts 230 facing each other may be 4.

Referring to FIGS. 6 and 7, N (herein, N is an integer of 2 to 7) cell metal contacts 210 may be in a line in the second horizontal direction (the Y direction) that is perpendicular to the extension direction of the plurality of word line cuts 230, between two of the plurality of word line cuts 230 facing each other. In addition, between the two of the plurality of word line cuts 230 facing each other, N+1 supports 220 arranged in a line around cell metal contacts 210 may be included. For example, the number of cell metal contacts 210 divided by the number of supports 220 in a unit block may be greater than or equal to ⅔.

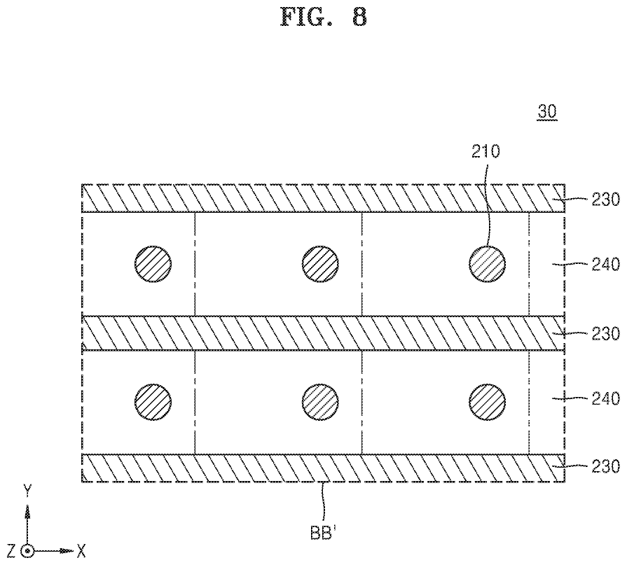

Referring to FIG. 8, a semiconductor memory device 30 may include the plurality of cell metal contacts 210 in the extension region EXR (see FIG. 5A).

The semiconductor memory device 30 according to example embodiments may include, in the extension region EXR (see FIG. 5A), the plurality of word line cuts 230 extending in the first horizontal direction (the X direction), and cutting a stacked structure of the plurality of word line plates 130 (see FIG. 5B) and the plurality of mold insulating layers 140 (see FIG. 5B) in the vertical direction (the Z direction).

Herein, cell metal contacts 210 may be in a line in the first horizontal direction (the X direction) between two of the plurality of word line cuts 230 facing each other. In addition, cylindrical-shaped supports 220 may not be between cell metal contacts 210 facing each other in the first horizontal direction (the X direction).

In the semiconductor memory device 30 according to example embodiments, as described above, supports 220 may reduce a problem, such as bending of the mold insulating layer 140 (see FIG. 5B). Herein, because a thick mold insulating layer 140 (see FIG. 5B) has a supporting force, the problem, such as bending, is reduced. Accordingly, even though supports 220 for supporting the mold insulating layer 140 (see FIG. 5B) are not arranged, a word line cut 230 and a cell metal contact 210 may provide stability.

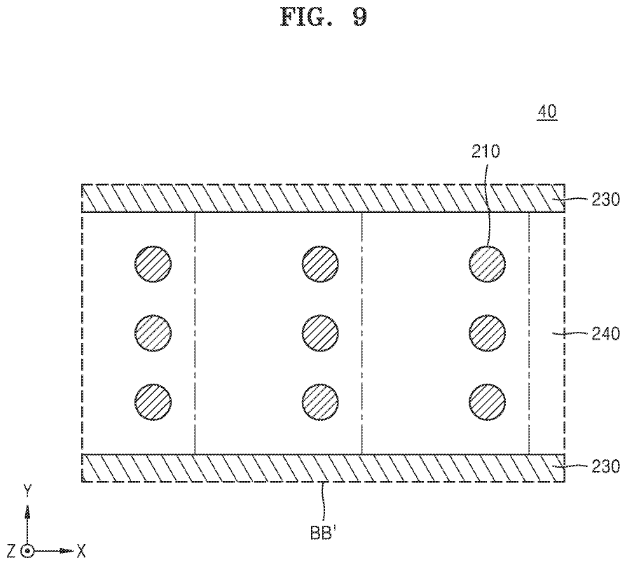

Referring to FIG. 9, a semiconductor memory device 40 may include the plurality of cell metal contacts 210 in the extension region EXR (see FIG. 5A).

The semiconductor memory device 40 according to example embodiments may include, in the extension region EXR (see FIG. 5A), the plurality of word line cuts 230 extending in the first horizontal direction (the X direction), and cutting a stacked structure of the plurality of word line plates 130 (see FIG. 5B) and the plurality of mold insulating layers 140 (see FIG. 5B) in the vertical direction (the Z direction).

Herein, cell metal contacts 210 may be in a line in the first horizontal direction (the X direction) between two of the plurality of word line cuts 230 facing each other. In addition, cylindrical-shaped supports 220 may not be between cell metal contacts 210 facing each other in the first horizontal direction (the X direction). In addition, three cell metal contacts 210 may be in a line in the second horizontal direction (the Y direction) between the two of the plurality of word line cuts 230 facing each other.

In the semiconductor memory device 40 according to example embodiments, as described above, supports 220 may reduce a problem, such as bending of the mold insulating layer 140 (see FIG. 5B). Herein, because a thick mold insulating layer 140 (see FIG. 5B) has a supporting force, the problem, such as bending, is reduced. Accordingly, even though supports 220 for supporting the mold insulating layer 140 (see FIG. 5B) are not arranged, a word line cut 230 and a cell metal contact 210 may provide stability.

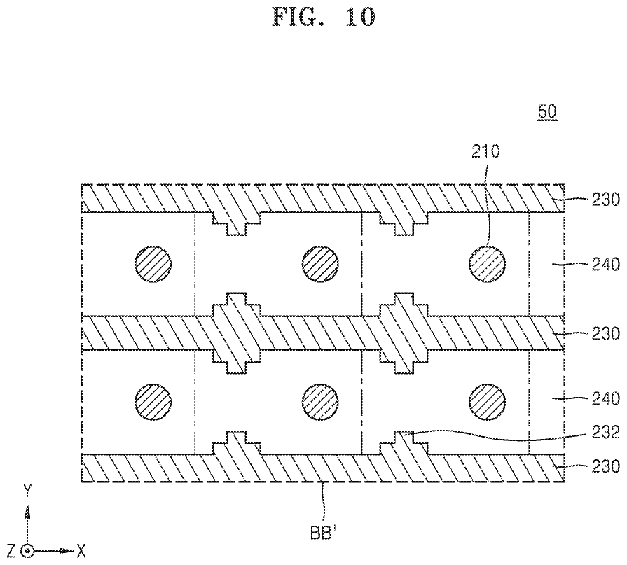

Referring to FIG. 10, a semiconductor memory device 50 may include the plurality of cell metal contacts 210 in the extension region EXR (see FIG. 5A).

The semiconductor memory device 50 according to example embodiments may include, in the extension region EXR (see FIG. 5A), the plurality of word line cuts 230 extending in the first horizontal direction (the X direction), and cutting a stacked structure of the plurality of word line plates 130 (see FIG. 5B) and the plurality of mold insulating layers 140 (see FIG. 5B) in the vertical direction (the Z direction). A protrusion portion 232 protruding in the second horizontal direction (the Y direction) may be on each of portions of a sidewall of each of the plurality of word line cuts 230. The protrusion portion 232 on a word line cut 230 may be formed in a region between cell metal contacts 210 facing each other in the first horizontal direction (the X direction), but example embodiments are not limited thereto.

Herein, cell metal contacts 210 may be in a line in the first horizontal direction (the X direction) between two of the plurality of word line cuts 230 facing each other. In addition, cylindrical-shaped supports 220 may not be between cell metal contacts 210 facing each other in the first horizontal direction (the X direction).

In the semiconductor memory device 50 according to example embodiments, as described above, supports 220 may reduce a problem, such as bending of the mold insulating layer 140 (see FIG. 5B). Herein, because a thick mold insulating layer 140 (see FIG. 5B) has a supporting force, the problem, such as bending, is reduced. Accordingly, even though supports 220 for supporting the mold insulating layer 140 (see FIG. 5B) are not arranged, a protrusion portion 232 on a word line cut 230 and a cell metal contact 210 may provide stability.

While aspects of example embodiments have been particularly shown and described, it will be understood that various changes in form and details may be made therein without departing from the spirit and scope of the following claims.

What is claimed is:

1. A semiconductor memory device comprising:
a stacked structure comprising a plurality of word line plates and a plurality of mold insulating layers which extend in a first horizontal direction and a second horizontal direction, and are alternately stacked in a vertical direction in a cell array region and an extension region, the first horizontal direction crossing the second horizontal direction and the plurality of word line plates forming a staircase structure in the extension region;
a vertical bit line extending into the stacked structure in the cell array region;
a plurality of selection layers between the plurality of word line plates and the vertical bit line; and
a vertical channel transistor connected to one end of the vertical bit line,
wherein a first thickness of each of the plurality of mold insulating layers is about 1.5 times to about 3 times a second thickness of each of the plurality of word line plates.

2. The semiconductor memory device of claim 1, wherein the plurality of selection layers comprise a material having an ovonic threshold switch characteristic.

3. The semiconductor memory device of claim 1, further comprising:
a plurality of word line cuts extending in the first horizontal direction, and extending into the stacked structure in the vertical direction in the cell array region and the extension region; and
a peripheral circuit structure beneath the stacked structure and comprising a peripheral circuit.

4. The semiconductor memory device of claim 3, further comprising, in the extension region, a plurality of cell metal contacts electrically connected to the plurality of word line plates, electrically isolated from other word line plates under a corresponding word line plate while penetrating the other word line plates, and electrically connected to the peripheral circuit of the peripheral circuit structure,
wherein at least two cell metal contacts are in a line in the second horizontal direction between two of the plurality of word line cuts facing each other.

5. The semiconductor memory device of claim 4, further comprising cylindrical supports extending in the vertical direction between cell metal contacts facing each other in the first horizontal direction.

6. The semiconductor memory device of claim 5, wherein a first diameter of each of the cell metal contacts is about 1.5 times to about 2.5 times a second diameter of each of the cylindrical supports.

7. The semiconductor memory device of claim 5, wherein, between the two of the plurality of word line cuts, a first number of cylindrical supports arranged in a line in the second horizontal direction is greater by 1 than a second number of cell metal contacts arranged in a line in the second horizontal direction.

8. The semiconductor memory device of claim 4, wherein no cylindrical supports are between cell metal contacts facing each other in the first horizontal direction.

9. The semiconductor memory device of claim 8, wherein, in the extension region, each of the plurality of word line cuts comprises a protrusion portion extending in the second horizontal direction on a portion of a sidewall thereof.

10. The semiconductor memory device of claim 9, wherein the protrusion portion is formed in a region between the cell metal contacts facing each other in the first horizontal direction.

11. A semiconductor memory device comprising:
a stacked structure comprising a plurality of word line plates and a plurality of mold insulating layers alternately stacked in a cell array region and an extension region, a first thickness of each of the plurality of mold insulating layers being about 1.5 times to about 3 times a second thickness of each of the plurality of word line plates;
a plurality of word line cuts extending in a horizontal direction, and extending into the stacked structure in a vertical direction in the cell array region and the extension region;
a peripheral circuit structure beneath the stacked structure and comprising a peripheral circuit;
a plurality of cell metal contacts extending through at least one of the plurality of word line plates in the extension region to be electrically connected to the peripheral circuit of the peripheral circuit structure;
a vertical bit line extending into the stacked structure in the cell array region;
a plurality of selection layers, each of the plurality of selection layers comprising a selective material between a corresponding word line plate and the vertical bit line, a first selective electrode between the selective material and the vertical bit line, and a second selective electrode between the corresponding word line plate and the selective material; and
a vertical channel transistor connected to one end of the vertical bit line.

12. The semiconductor memory device of claim 11, wherein the vertical channel transistor comprises:
a drain region, a channel region, and a source region sequentially provided from the vertical bit line;
a gate line surrounding the channel region; and
a gate insulating layer between the channel region and the gate line.

13. The semiconductor memory device of claim 11, wherein N cell metal contacts are in a line in a horizontal direction that is perpendicular to an extension direction of the plurality of word line cuts, between two of the plurality of word line cuts facing each other, N being an integer greater than one.

14. The semiconductor memory device of claim 13, further comprising N+1 cylindrical supports arranged in a line around the N cell metal contacts between the two of the plurality of word line cuts.

15. The semiconductor memory device of claim 13, wherein no cylindrical supports are around the N cell metal contacts between the two of the plurality of word line cuts.

16. A semiconductor memory device comprising:
a stacked structure comprising a plurality of word line plates and a plurality of mold insulating layers alternately stacked, a first thickness of each of the plurality of mold insulating layers being about 1.5 times to about 3 times a second thickness of each of the plurality of word line plates;
a vertical bit line extending into the stacked structure; and
a plurality of selection layers between the plurality of word line plates and the vertical bit line.

17. The semiconductor memory device of claim 16, wherein the plurality of selection layers comprise a material having an ovonic threshold switch characteristic.

18. The semiconductor memory device of claim 16, further comprising:
a plurality of word line cuts extending in a horizontal direction, and extending into the stacked structure in a vertical direction; and
a plurality of cell metal contacts electrically connected to the plurality of word line plates, respectively, while penetrating a corresponding word line plate and electrically isolated from other word line plates under the corresponding word line plate,
wherein the plurality of cell metal contacts are in a line in the horizontal direction between two of the plurality of word line cuts facing each other.

19. The semiconductor memory device of claim 18, wherein no cylindrical supports are between the plurality of cell metal contacts.

20. The semiconductor memory device of claim 18, wherein each of the plurality of word line cuts comprises a protrusion portion protruding on a portion of a sidewall thereof.
